(19) United States
(12) Patent Application Publication
(10) Pub. No.: US 2020/0338807 A1
(43) Pub. Date: Oct. 29, 2020

(54) METHOD FOR PRODUCING CONCAVE-CONVEX STRUCTURE, LAMINATE TO BE USED IN METHOD FOR PRODUCING CONCAVE-CONVEX STRUCTURE, AND METHOD FOR PRODUCING LAMINATE

(71) Applicant: MITSUI CHEMICALS, INC., Minato-ku, Tokyo (JP)

(72) Inventors: Takashi ODA, Ichihara-shi, Chiba (JP); Hisanori OHKITA, Chiba-shi, Chiba (JP); Makoto NAKASHIMA, Ichihara-shi, Chiba (JP)

(73) Assignee: MITSUI CHEMICALS, INC., Minato-ku, Tokyo (JP)

(21) Appl. No.: 16/962,704

(22) PCT Filed: Dec. 5, 2018
(86) PCT No.: PCT/JP2018/044711

§ 371 Date: Jul. 16, 2020

(30) Foreign Application Priority Data
Jan. 19, 2018 (JP) 2018-006980

(51) Int. Cl. B29C 59/00; B29C 59/02; C08G 61/06; H01L 21/027

(52) U.S. Cl. CPC B29C 59/005; B29C 59/026; B29K 2027/12; C08G 61/06; H01L 21/0271; B29C 59/002

(57) ABSTRACT

Provided is a method for producing a concave-convex structure, the method including a preparation step of preparing a laminate including a base material layer, a photocurable resin layer containing a fluorine-containing cyclic olefin polymer (A), a photocurable compound (B) and a photocuring initiator (C), and a protective film layer in this order; a peeling step of peeling the protective film layer of the laminate; a pressing step of pressing a mold against the photocurable resin layer exposed in the peeling step; and a light irradiation step of irradiating the photocurable resin layer with light, in which a concave-convex structure having an inverted concave-convex pattern of the mold is produced.

### TECHNICAL FIELD

The present invention relates to a method for producing a concave-convex structure, a laminate to be used in a method for producing a concave-convex structure, and a method for producing the laminate.

### BACKGROUND ART

As a method for forming a fine concave-convex pattern on a surface of a substrate, a photolithography method and a nanoimprint lithography method are known.

The photolithography method involves an expensive apparatus and a complicated process, whereas the nanoimprint lithography method has an advantage that a fine concave-convex pattern can be formed on the surface of a substrate by a simple apparatus and a simple process. In addition, the nanoimprint lithography method is considered to be a preferred method for forming a relatively wide and deep concave-convex structure and various shapes such as a dome shape, a quadrangular pyramid, and a triangular pyramid.

The method for forming a fine concave-convex pattern on a substrate by using the nanoimprint lithography method is carried out by the following procedure as an example.

(1) A photocurable compound or a varnish obtained by dissolving the photocurable compound in a solvent is applied onto a desired substrate, and the solvent and/or other organic compounds are removed by heating in a drying furnace as necessary.

(2) Next, a mold having a desired concave-convex pattern is brought into contact therewith, followed by light irradiation curing.

(3) Thereafter, the mold is released to obtain a processed substrate having a concave-convex structure formed on the substrate.

Known techniques of optical nanoimprinting using a photocurable compound include, for example, Patent Documents 1 and 2. It is considered that the optical nanoimprinting can form a desired concave-convex pattern with high dimensional accuracy, and can be easily carried out with a large area without applying a high pressure to a wide area.

### RELATED DOCUMENT

### Patent Document

[Patent Document 1] Pamphlet of International Publication No. WO 2009/101913

[Patent Document 2] Pamphlet of International Publication No. WO 2010/098102

### SUMMARY OF THE INVENTION

### Technical Problem

In recent years, in a process of producing an electronic device or a circuit such as a display or a semiconductor, emission of organic compounds and the like used in the process is also increasing in accordance with a production volume that is increasing year by year, and therefore regulations on the types and amounts of organic compounds such as solvents used in processes are increasing from the viewpoint of disposal costs, environmental issues, human (worker) health, and the like. As one of the solutions to the above-mentioned situation, adaptation of a process without using a solvent (a so-called dry process or the like) is widely demanded. Various regulations are applied without exception in the process to which the nanoimprint lithography method is adapted. Therefore, it is required to create a material and/or process that has high accuracy in forming a fine concave-convex pattern and does not generate volatile components such as a solvent.

The photocurable resin compositions for nanoimprint described in Patent Documents 1 and 2 described above basically contain a solvent. Therefore, volatile components of an organic compound such as a solvent may be generated in a case where the imprint process is carried out. That is, there is a possibility that an additional capital investment for removing volatile components is required, or a problem may occur in the health of workers.

The present invention has been made in view of such circumstances. That is, an object of the present invention is to suppress emission of an organic compound such as a solvent at the time of producing a concave-convex structure by optical nanoimprinting.

### Solution to Problem

As a result of the study, the present inventors have made the invention provided below and found that the above-mentioned object can be achieved.

The present invention is as follows.

1.

A method for producing a concave-convex structure, the method including:

a preparation step of preparing a laminate including a base material layer, a photocurable resin layer containing a fluorine-containing cyclic olefin polymer (A), a photocurable compound (B) and a photocuring initiator (C), and a protective film layer in this order;

a peeling step of peeling the protective film layer of the laminate;

a pressing step of pressing a mold against the photocurable resin layer exposed in the peeling step; and

a light irradiation step of irradiating the photocurable resin layer with light,

in which a concave-convex structure having an inverted concave-convex pattern of the mold is produced.

2.

The method for producing a concave-convex structure according to 1, in which a mass ratio ((A)/(B)) of a content of the fluorine-containing cyclic olefin polymer (A) to a content of the photocurable compound (B) in the photocurable resin layer is equal to or more than 1/99 and equal to or less than 80/20.

3.

The method for producing a concave-convex structure according to 1 or 2, in which the photocurable compound (B) contains a cationically polymerizable ring-opening polymerizable compound.

4.

The method for producing a concave-convex structure according to any one of 1 to 3, in which the photocurable compound (B) has a boiling point of equal to or higher than 150° C. and equal to or lower than 350° C. at 1 atm.

5.

The method for producing a concave-convex structure according to any one of 1 to 4, in which the fluorine-containing cyclic olefin polymer (A) includes a structural unit represented by General Formula (1).

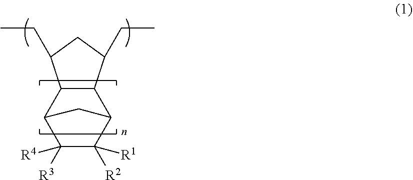

In General Formula (1),

at least one of R¹ to R⁴ is a fluorine-containing group selected from the group consisting of fluorine, a fluorine-containing alkyl group having 1 to 10 carbon atoms, a fluorine-containing alkoxy group having 1 to 10 carbon atoms, and a fluorine-containing alkoxyalkyl group having 2 to 10 carbon atoms,

in a case where R¹ to R⁴ are not a fluorine-containing group, R¹ to R⁴ are an organic group selected from the group consisting of hydrogen, an alkyl group having 1 to 10 carbon atoms, an alkoxy group having 1 to 10 carbon atoms, and an alkoxyalkyl group having 2 to 10 carbon atoms, and

R¹ to R⁴ may be the same as or different from each other, and R¹ to R⁴ may be bonded to each other to form a ring structure, and n represents an integer of 0 to 2.

6.

The method for producing a concave-convex structure according to any one of 1 to 5, in which the base material layer is formed of a resin film.

7.

A laminate to be used in a method for producing a concave-convex structure having an inverted concave-convex pattern of a mold, the laminate including:

a base material layer;

a photocurable resin layer containing a fluorine-containing cyclic olefin polymer (A), a photocurable compound (B) and a photocuring initiator (C); and

a protective film layer in this order.

8.

The laminate according to 7, in which a mass ratio ((A)/(B)) of a content of the fluorine-containing cyclic olefin polymer (A) to a content of the photocurable compound (B) in the photocurable resin layer is equal to or more than 1/99 and equal to or less than 80/20.

9.

The laminate according to 7 or 8, in which the photocurable compound (B) contains a cationically polymerizable ring-opening polymerizable compound.

10.

The laminate according to any one of 7 to 9, in which the photocurable compound (B) has a boiling point of equal to or higher than 150° C. and equal to or lower than 350° C. at 1 atm.

11.

The laminate according to any one of 7 to 10, in which the fluorine-containing cyclic olefin polymer (A) includes a structural unit represented by General Formula (1).

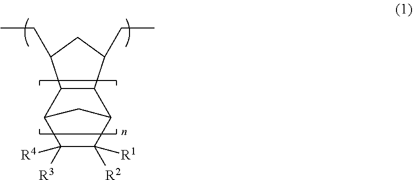

In General Formula (1),

at least one of R¹ to R⁴ is a fluorine-containing group selected from the group consisting of fluorine, a fluorine-containing alkyl group having 1 to 10 carbon atoms, a fluorine-containing alkoxy group having 1 to 10 carbon atoms, and a fluorine-containing alkoxyalkyl group having 2 to 10 carbon atoms,

in a case where R¹ to R⁴ are not a fluorine-containing group, R¹ to R⁴ are an organic group selected from the group consisting of hydrogen, an alkyl group having 1 to 10 carbon atoms, an alkoxy group having 1 to 10 carbon atoms, and an alkoxyalkyl group having 2 to 10 carbon atoms, and

R¹ to R⁴ may be the same as or different from each other, and R¹ to R⁴ may be bonded to each other to form a ring structure, and n represents an integer of 0 to 2.

12.

The laminate according to any one of 7 to 11, in which the base material layer is formed of a resin film.

13.

The method for producing the laminate according to any one of 7 to 12, the method including:

a step of forming a photocurable resin layer containing a fluorine-containing cyclic olefin polymer (A), a photocurable compound (B) and a photocuring initiator (C) on a surface of a base material layer; and

a step of forming a protective film layer on the surface of the photocurable resin layer.

### Advantageous Effects of Invention

According to the present invention, emission of an organic compound such as a solvent at the time of producing a concave-convex structure by optical nanoimprinting can be suppressed.

In addition, the photocurable resin layer in the laminate of the present invention contains a fluorine-containing cyclic olefin polymer, that is, a polymer containing fluorine and having a cyclic olefin skeleton. By a configuration of “containing fluorine”, the peeling property of the protective film layer of the laminate can be improved, and the peeling property at the time of producing the concave-convex structure can also be improved, so that a concave-convex structure on which the pattern of the mold is accurately transferred can be obtained. Further, it is considered that, by a configuration of “containing a polymer having a cyclic olefin skeleton”, liquid dripping of the photocurable resin layer or the like does not occur during the production of a laminate produced in a form covered with a protective film, and the shape retention of the produced concave-convex structure can be improved.

### BRIEF DESCRIPTION OF THE DRAWINGS

The above and other objects, features and advantages will become more readily apparent from the preferred embodiments described below and the accompanying drawings.

FIG. 1 is a diagram for explaining a method for producing a concave-convex structure according to the present embodiment.

FIG. 2 is a schematic diagram for supplementing an evaluation method in the Examples.

### DESCRIPTION OF EMBODIMENTS

Hereinafter, embodiments of the present invention will be described in detail with reference to the drawings.

In all the drawings, the same components are denoted by the same reference numerals, and description thereof will not be repeated.

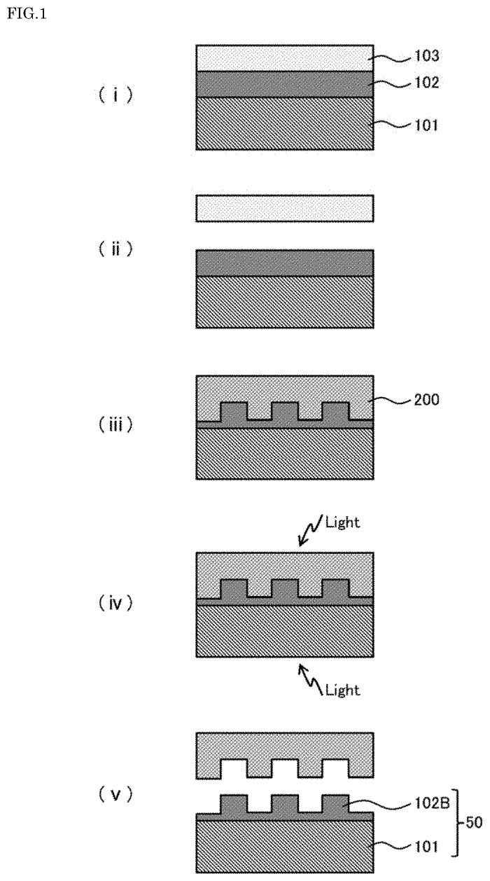

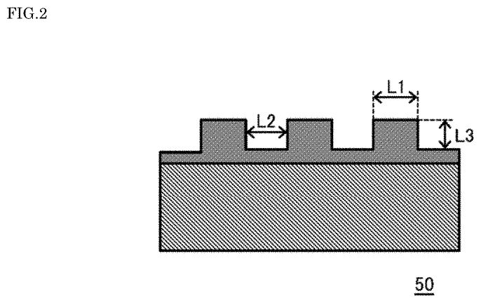

In order to avoid complexity, (i) in a case where there are a plurality of the same components in the same drawing, only one of the components is denoted by a reference numeral, and all the components are not denoted by a reference numeral, or (ii) especially in FIG. 2 and subsequent figures, the same components as those in FIG. 1 may not be denoted by reference numerals again.

All drawings are for illustration only. The shapes, dimensional ratios, and the like of each member in the drawings do not necessarily correspond to actual articles.

Unless otherwise specified, the notation “a to b” in the description of the numerical range in the present specification means equal to or more than a and equal to or less than b. For example, “1 to 5% by mass” means “equal to or more than 1% by mass and equal to or less than 5% by mass”.

In the present specification, in a case where a group (atomic group) is denoted without specifying whether substituted or unsubstituted, the group includes both a group having a substituent and a group having no substituent. For example, the term “alkyl group” includes not only an alkyl group having no substituent (unsubstituted alkyl group) but also an alkyl group having a substituent (substituted alkyl group).

The expression “(meth) acrylic” in the present specification represents a concept including both acrylic and methacrylic. The same applies to similar expressions such as “(meth)acrylate”.

<Method for Producing Concave-Convex Structure>

The method for producing a concave-convex structure according to the present embodiment is

a method for producing a concave-convex structure, the method including:

a preparation step of preparing a laminate including a base material layer, a photocurable resin layer containing a fluorine-containing cyclic olefin polymer (A), a photocurable compound (B) and a photocuring initiator (C), and a protective film layer in this order (hereinafter, also simply referred to as a “preparation step”);

a peeling step of peeling the protective film layer of the laminate (hereinafter, also simply referred to as a “peeling step”);

a pressing step of pressing a mold against the photocurable resin layer exposed in the peeling step (hereinafter, also simply referred to as a “pressing step”); and

a light irradiation step of irradiating the photocurable resin layer with light (hereinafter, also simply referred to as a “light irradiation step”), in which a concave-convex structure having an inverted concave-convex pattern of the mold is produced.

By producing the concave-convex structure by such steps, emission of an organic compound such as a solvent can be suppressed without the need for an application step of a resin composition containing a solvent. That is, it is friendly to the environment and humans (workers) since volatile components such as a solvent are not substantially emitted during the production of the concave-convex structure.

In addition, the method for producing a concave-convex structure according to the present embodiment does not require steps such as coating and baking that generate volatile components of the organic substance. Thereby, safety at the time of carrying out the nanoimprint process can be improved.

Furthermore, it is considered that, since there are no steps such as coating and baking, a concave-convex structure with excellent dimensional accuracy can be produced more easily by the optical nanoimprinting method than in the related art, which thus has high industrial utility value.

In addition, in the method for producing a concave-convex structure according to the present embodiment, the photocurable resin layer in the laminate contains the fluorine-containing cyclic olefin polymer (A). Thereby, it is considered that the following effects can also be obtained: (i) it is easy to peel off the protective film in the peeling step, (ii) the releasability of the mold is good, and (iii) since the polymer has an appropriate rigidity, it is easy to form a coating film having an appropriate ‘hardness’ (the photocurable resin layer does not “leak out” unintentionally due to pressure or the like).

Hereinafter, each step will be described more specifically with reference to FIG. 1.

(Preparation Step: FIG. 1 (i))

In the preparation step, as shown in FIG. 1 (i), a laminate including a base material layer 101, a photocurable resin layer 102 containing a fluorine-containing cyclic olefin polymer (A), a photocurable compound (B) and a photocuring initiator (C) (hereinafter, also simply referred to as a “photocurable resin layer 102”), and a protective film layer 103 in this order is prepared.

Here, the term “preparation” is to be interpreted in a broad sense. That is, an embodiment in which a person who carries out the subsequent peeling step, pressing step, light irradiation step, and the like produces and prepares a laminate is naturally included in the “preparation step”. In addition, the preparation step here also includes an embodiment in which a laminate produced by a third party different from the person who carries out the subsequent peeling step, pressing step, light irradiation step, and the like is transferred and prepared.

Specific embodiments, constituent materials, production methods, and the like of the laminate will be described in detail in the section of <Laminate>.

(Peeling Step: FIG. 1 (ii))

In the peeling step, the protective film layer 103 of the laminate is peeled.

The method of peeling is not particularly limited, and a known method can be applied. For example, the end portion of the protective film layer 103 may be grasped and then the protective film layer 103 may be peeled off from the end portion of the laminate as a starting point. Alternatively, an adhesive tape may be attached to the protective film layer 103 which is then peeled off from the tape as a starting point. Furthermore, in a case where it is carried out by a continuous method such as a roll-to-roll method, a method may be used in which the end portion of the protective film layer 103 is fixed to a take-up roll and then the protective film layer 103 is peeled off while rotating the roll at a speed corresponding to the peripheral speed of the step.

The photocurable resin layer 102 is exposed by peeling the protective film layer 103 from the laminate.

(Pressing Step: FIG. 1 (iii))

In the pressing step, a mold 200 is pressed against the photocurable resin layer 102 exposed in the peeling step.

Due to the pressing, the photocurable resin layer 102 is deformed in accordance with the concave-convex pattern of the mold 200. Then, as shown in FIG. 1 (iii), the mold 200 and the photocurable resin layer 102 are brought into close contact with almost no gap.

The pressing method can be carried out by a known method. For example, there is a method of pressing with a suitable pressure in a state where the photocurable resin layer 102 is brought into contact with the concave-convex pattern of the mold 200. The pressure at this time is not particularly limited, but is, for example, preferably equal to or less than 10 MPa, more preferably equal to or less than 5 MPa, and particularly preferably equal to or less than 1 MPa. This pressure is appropriately selected depending on the pattern shape, aspect ratio, material, and the like of the mold 200. The lower limit of the pressure is not particularly limited as long as the photocurable resin layer 102 is deformed in accordance with the concave-convex pattern of the mold 200, and is, for example, equal to or more than 0.1 MPa.

The shape and the like of the mold 200 used here are not particularly limited.

The shape of a convex portion and a concave portion of the mold 200 may be a dome shape, a quadrangular prism shape, a column shape, a prism shape, a quadrangular pyramid shape, a triangular pyramid shape, a polyhedral shape, a hemispherical shape, or the like. Examples of the cross-sectional shape of the convex portion and the concave portion of the mold 200 include a quadrangular cross section, a triangular cross section, and a semicircular cross section.

The width of the convex portion and/or the concave portion of the mold 200 is not particularly limited, but is, for example, 10 nm to 50 μm and preferably 20 nm to 10 μm. In addition, the depth of the concave portion and/or the height of the convex portion is not particularly limited, but is, for example, 10 nm to 50 μm and preferably 50 nm to 10 μm. Further, the aspect ratio of the ratio of the width of the convex portion to the height of the convex portion is preferably 0.1 to 500 and more preferably 0.5 to 20.

Examples of the material of the mold 200 include a metal material such as nickel, iron, stainless steel, germanium, titanium, or silicon; an inorganic material such as glass, quartz, or alumina; a resin material such as polyimide, polyamide, polyester, polycarbonate, polyphenylene ether, polyphenylene sulfide, polyacrylate, polymethacrylate, polyarylate, epoxy resin, or silicone resin; and a carbon material such as diamond or graphite.

(Light Irradiation Step: FIG. 1 (iv))

In the light irradiation step, the photocurable resin layer 102 is irradiated with light. More specifically, the photocurable resin layer 102 is irradiated with light while the pressure is applied in the pressing step to cure the photocurable resin layer 102.

The irradiation light is not particularly limited as long as it is capable of curing the photocurable resin layer 102, and examples thereof include ultraviolet light, visible light, and infrared light. Of these, light that generates radicals or ions from the photocuring initiator (C) is preferable. Specifically, a light beam having a wavelength of equal to or shorter than 400 nm, for example, a low-pressure mercury lamp, a medium-pressure mercury lamp, a high-pressure mercury lamp, an ultra-high-pressure mercury lamp, a chemical lamp, a black light lamp, a microwave excitation mercury lamp, a metal halide lamp, an i-line, a g-line, a KrF excimer laser light, or ArF excimer laser light can be used.

The integrated light amount of light irradiation can be set to, for example, 3 to 3000 mJ/cm².

The light irradiation may be carried out from the direction in which the base material layer 101 shown in FIG. 1 (iv) is positioned, may be carried out from the direction in which the mold 200 is positioned, or may be carried out from both directions. The direction of light irradiation maybe appropriately selected in consideration of the material (particularly, light transmittance) of the base material layer 101 and the mold 200, process suitability, and the like.

Light irradiation and heating may be used in combination for the purpose of accelerating the curing of the photocurable resin layer 102 and the like. The heating step may be carried out after the light irradiation step.

The heating temperature is preferably equal to or higher than room temperature (usually meaning 25° C.) and equal to or lower than 200° C. and more preferably equal to or higher than room temperature and equal to or lower than 150° C. The heating temperature may be appropriately selected in consideration of the heat resistance of the base material layer 101, the photocurable resin layer 102, and the mold 200, the improvement of productivity by promoting the curing, and the like.

(Mold Release Step: FIG. 1 (v))

The method for producing a concave-convex structure according to the present embodiment preferably includes a mold release step. Specifically, the photocurable resin layer 102 cured by the light irradiation step is separated from the mold 200 to obtain a concave-convex structure 50 having a concave-convex pattern 102B formed on the base material layer 101.

A known method can be applied to the mold release method. For example, the base material layer 101 maybe grasped and released from the end portion of the base material layer 101 as a starting point, or alternatively an adhesive tape may be attached to the base material layer 101, and then the base material layer 101 and the photocurable resin layer 102 may be separated from the mold 200 with the tape as a starting point. Furthermore, in a case where it is carried out by a continuous method such as a roll-to-roll method, for example, a method may be used in which the roll is rotated at a speed corresponding to the peripheral speed of the step, and the concave-convex structure 50 having the concave-convex pattern 102B formed on the base material layer 101 is peeled off while being wound.

Through the above-mentioned steps, the concave-convex structure 50 having an inverted concave-convex pattern of the mold 200 can be produced.

In the method for producing a concave-convex structure according to the present embodiment, it is particularly preferable that the above-mentioned preparation step and peeling step are carried out in separate places. By carrying out the preparation step, which may include the application of a coating liquid and the like, and the subsequent steps in separate places, the effects of reducing the emission (volatilization) of organic compounds and improving the safety during the nanoimprint process can be obtained more reliably.

In other words, it is preferable that (1) the laminate is first prepared and stored in the preparation step, (2) the stored laminate is transported to another place, and (3) the peeling step, the pressing step, the light irradiation step, the mold release step, and the like are carried out at the another place. By transporting the laminate prepared in the preparation step to another place and thereafter, carrying out the peeling step, the pressing step, the light irradiation step, the mold release step, and the like, the emission of volatile components during the production of the concave-convex structure can be reduced more reliably.

(Explanation of Uses, Application Methods, and the Like)

The method for producing a concave-convex structure according to the present embodiment can be applied to various imprint processes, and can be variously used in consideration of the user's purpose, resin properties, processes, and the like.

As an example, the method for producing a concave-convex structure according to the present embodiment can be preferably applied to the production of a so-called “replica mold”. That is, the method for producing a concave-convex structure according to the present embodiment can be used in order to produce an inexpensive disposable mold (replica mold) used to extend the life of an expensive mold (usually called a mother mold) processed by lithography or electron beam lithography, which is used in the nanoimprint lithography method. At this time, the mold 200 in the above-mentioned step corresponds to a mother mold, and the concave-convex structure 50 corresponds to a replica mold.

Since the photocurable resin layer 102 contains the fluorine-containing cyclic olefin polymer (A), the concave-convex structure 50 exhibits relatively good releasability and durability in a case of being used as the replica mold. In other words, the concave-convex structure 50 is preferably used as the replica mold in terms of good releasability derived from fluorine and high durability derived from a rigid cyclic olefin structure.

In addition, the concave-convex structure 50 and/or the concave-convex pattern 102B obtained by the method for producing a concave-convex structure according to the present embodiment may be used as a permanent film or the like which is used in a process member, a lens, a circuit, or the like. According to the embodiment, such a structure and/or pattern may be used as an etching mask which is used in an etching step in a case of producing a process member, a lens, a circuit, or the like.

More specifically, such a structure and/or pattern is preferably applied to members and products used in applications such as a display member with an antireflection function, a microlens array, a semiconductor circuit, a display high-brightness member, an optical waveguide, an antibacterial sheet, a cell culture bed, a building material with an antifouling function, a daily necessity, and a translucent mirror.

A microlens array will be described as an example of a method of using the concave-convex structure 50 and/or the concave-convex pattern 102B as an etching mask.

In a case where the base material layer 101 constituting the concave-convex structure 50 is made of quartz glass, (1) first, a hemispherical macro lens array structure to be the concave-convex pattern 102B is formed on the surface of the base material layer 101 according to the method for producing a concave-convex structure according to the present embodiment. Next, (2) dry etching is carried out in a gas atmosphere containing oxygen as a main component to etch the concave-convex pattern 102B layer. Further, (3) the gas atmosphere is switched to a CF-based gas, and dry etching is carried out again to process the quartz glass surface of the base material layer 101 into a shape following the shape of the concave-convex pattern 102B (in this case, a microlens array), thereby processing a desired microlens array. By such a method, the productivity can be greatly improved for the current mainstream cutting process.

Furthermore, in a case where the product performance matches the usage environment and conditions, the concave-convex structure 50 in a state in which a hemispherical macrolens array structure serving as the concave-convex pattern 102B is formed on the surface of the base material layer 101 may be used as a microlens array as it is.

<Laminate>

The laminate according to the present embodiment is used for a method for producing a concave-convex structure having an inverted concave-convex pattern of the mold (more specifically, the method described in the above section <Method for producing concave-convex structure>). The laminate according to the present embodiment includes a base material layer, a photocurable resin layer containing a fluorine-containing cyclic olefin polymer (A), a photocurable compound (B) and a photocuring initiator (C) (hereinafter, simply referred to as “photocurable resin layer”), and a protective film layer in this order.

In a case where the laminate according to the present embodiment is applied to the above-mentioned method for producing a concave-convex structure, it is possible to produce the concave-convex structure while suppressing emission of an organic compound such as a solvent.

In addition, the user of the laminate according to the present embodiment can obtain a concave-convex pattern (structure) by a dry process by a simple method (in which an application step is unnecessary) of carrying out optical imprinting by peeling off the protective film layer.

Furthermore, it is considered that, since the photocurable resin layer in the laminate contains the fluorine-containing cyclic olefin polymer (A), effects such as easy peeling of the protective film in the peeling step and good releasability of the mold can be obtained.

In addition, it is considered that, since the laminate according to the present embodiment has a protective film layer disposed on the surface of the photocurable resin layer, effects such as prevention of dust from adhering to the surface of the photocurable resin layer, suppression of volatilization of compounds contained in the photocurable resin layer, prevention of deterioration of the photocuring initiator due to moisture and oxygen in the atmosphere, and long-term storage stability of the laminate can also be obtained.

Each layer of the laminate will be described in detail with reference to FIG. 1 (i).

(Base Material Layer 101)

The material of the base material layer 101 is not particularly limited, and is made of, for example, an organic material or an inorganic material. In addition, as for the properties of the material of the base material layer, for example, a sheet-like, film-like, or plate-like material can be used.

More specifically, in a case where the base material layer 101 is made up of an organic material, for example, one or more of various resins such as polyester (such as polyacetal, polyamide, polycarbonate, polyphenylene ether, polybutylene terephthalate, polyethylene terephthalate, or polyethylene terenaphthalate), polyolefin (such as polyethylene or polypropylene), poly(meth)acrylate, polysulfone, polyethersulfone, polyphenylenesulfide, polyetheretherketone, polyimide, polyetherimide, polyacetylcellulose, and fluororesin can be used as a raw material. Then, the base material layer 101 can be obtained by processing the raw material by a method such as injection molding, extrusion molding, hollow molding, thermoforming, or compression molding.

In another aspect, the base material layer 101 may be made of a single-layer base material obtained by curing a photocurable monomer such as (meth)acrylate, styrene, epoxy, or oxetane by light irradiation in the presence of a polymerization initiator, or a base material obtained by coating such a photocurable monomer on an organic or inorganic material.

In a case where the base material layer 101 is made of an inorganic material, examples of the constituent material thereof include copper, gold, platinum, nickel, aluminum, silicon, stainless steel, quartz, soda glass, sapphire, and carbon fiber.

Regardless of whether the constituent material of the base material layer 101 is an organic material or an inorganic material, some treatment may be carried out on the surface of the base material layer 101 in order to develop good adhesiveness to the photocurable resin layer 102. Examples of such a treatment include close contact treatments such as a corona treatment, an atmospheric pressure plasma treatment, and an easy adhesion coating treatment.

In addition, regardless of whether the constituent material of the base material layer 101 is an organic material or an inorganic material, the base material layer 101 may be a single layer or may have a configuration of two or more layers.

The base material layer 101 is preferably a resin film. The base material layer 101 is preferably, for example, a resin film containing any of the above-mentioned resins. Since the base material layer 101 is not an inorganic material but a resin film, the user can easily cut the resin film into a desired shape and size and then use the cut resin film, and the laminate can be rolled in a case of storing the laminate, that is, there is an advantage of space saving.

From another viewpoint, it is preferable that the light transmittance of the base material layer 101 is high. Thereby, advantages can be obtained such that (i) in a case of producing the concave-convex structure (for example, at the time of the above-mentioned light irradiation step), light can be applied from the side of the base material layer 101 to accelerate the curing reaction, (ii) the pressing step and the light irradiation step can be easily confirmed visually, and (iii) the degree of freedom in device design can be increased from the direction of light irradiation.

From the viewpoint of (i), it may be preferable that the base material layer 101 has a high transmittance in a wavelength region of light in which the photocuring initiator (C) described below reacts. More preferably, the base material layer 101 preferably has a high transmittance of light in the ultraviolet region. For example, the transmittance of light having a wavelength of equal to or longer than 200 nm and equal to or shorter than 400 nm is preferably equal to or more than 50% and equal to or less than 100%, more preferably equal to or more than 70% and equal to or less than 100%, and still more preferably equal to or more than 80% and equal to or less than 100%.

From the viewpoint of (ii), it is preferable that the transmittance of light in the visible region of the base material layer 101 is high. For example, the transmittance of light having a wavelength of equal to or longer than 500 nm and equal to or shorter than 1000 nm is preferably equal to or more than 50% and equal to or less than 100%, more preferably equal to or more than 70% and equal to or less than 100%, and still more preferably equal to or more than 80% and equal to or less than 100%.

In addition, since most of the resin films have high transparency, it can be said that the resin film is preferable as the base material layer 101 also in terms of light transmittance.

The thickness of the base material layer 101 is not particularly limited, and is appropriately adjusted according to various purposes, for example, good handleability of the laminate, dimensional accuracy of the concave-convex structure to be obtained, and the like.

The thickness of the base material layer 101 is, for example, 1 to 10000 μm, specifically 5 to 5000 μm, and more specifically 10 to 1000 μm.

The shape of the entire base material layer 101 is not particularly limited, and may be, for example, a plate shape, a disk shape, a roll shape, or the like.

(Photocurable Resin Layer 102)

The photocurable resin layer 102 contains a fluorine-containing cyclic olefin polymer (A), a photocurable compound (B) and a photocuring initiator (C). These components will be described below.

Fluorine-Containing Cyclic Olefin Polymer (A)

The fluorine-containing cyclic olefin polymer (A) is not particularly limited as long as it is a polymer containing fluorine and including a structural unit derived from a cyclic olefin. Since this polymer contains fluorine, it is considered to be advantageous in terms of clean peeling of the protective film layer 103 and in terms of releasability during the imprint process. In addition, the inclusion of the cyclic structure in the polymer is considered to have advantages such as mechanical strength and high etching resistance.

Furthermore, the fluorine-containing cyclic olefin polymer (A) has a high polarity as a whole polymer, and tends to have relatively good compatibility with a general-purpose organic solvent or a photocurable compound which is not soluble in a normal fluoropolymer, tends to be amorphous, and does not tend to be cured by light irradiation. It is considered that a sufficiently transparent resin layer (photocurable resin layer) necessary for obtaining curing by light irradiation with good compatibility with a photocurable compound in a case where the photocurable resin layer 102 is formed on the base material layer 101 by, for example, “dissolving in the photocurable compound” is formed, and therefore the photocurable resin layer 102 has a viscosity suitable for forming a fine concave-convex structure, which contributes to a reduction in problems such as liquid dripping leading to roughening of the film surface.

In addition, the fluorine-containing cyclic olefin polymer (A) has a high transmittance of light and/or tends to make light transmission uniform in a case of being formed into a film, from the viewpoint of the electronic specificity of the C—F bond and the above-mentioned non-crystallinity (amorphousness). Therefore, it is considered that, in a case where the photocurable resin layer 102 contains the fluorine-containing cyclic olefin polymer (A), transmission of light to be applied in a case where the photocurable resin layer 102 is photocured tends to be uniform. In other words, it is considered that the curing is carried out uniformly, whereby the photocurable resin layer 102 can be cured uniformly without unevenness.

The fluorine-containing cyclic olefin polymer (A) preferably contains a structural unit represented by General Formula (1).

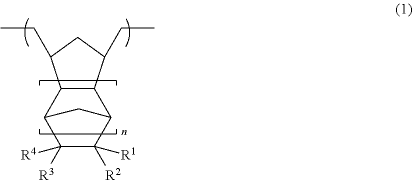

In General Formula (1),

at least one of R¹ to R⁴ is a fluorine-containing group selected from the group consisting of fluorine, a fluorine-containing alkyl group having 1 to 10 carbon atoms, a fluorine-containing alkoxy group having 1 to 10 carbon atoms, and a fluorine-containing alkoxyalkyl group having 2 to 10 carbon atoms,

in a case where R¹ to R⁴ are not a fluorine-containing group, R¹ to R⁴ are an organic group selected from the group consisting of hydrogen, an alkyl group having 1 to 10 carbon atoms, an alkoxy group having 1 to 10 carbon atoms, and an alkoxyalkyl group having 2 to 10 carbon atoms, and

R¹ to R⁴ may be the same as or different from each other, and R¹ to R⁴ may be bonded to each other to form a ring structure, and

n represents an integer of 0 to 2.

The fluorine-containing cyclic olefin polymer (A) containing the structural unit represented by General Formula (1) has a hydrocarbon structure in a main chain thereof and a fluorine-containing aliphatic ring structure in a side chain thereof. Therefore, a hydrogen bond can be formed between molecules or within a molecule, and in a case where the photocurable compound (B) and the photocuring initiator (C) described later are included, long-term storage stability is good. In addition, in a state after the peeling of the protective film layer 103, an appropriate embedding property necessary for forming the concave-convex structure is exhibited, and the shape of the mold can be formed with good releasability and good dimensional accuracy in the peeling after the photocuring.

Further, the fluorine-containing cyclic olefin polymer (A) has a relatively large polarity in the molecule by having a hydrocarbon structure in the main chain thereof and fluorine or a fluorine-containing substituent in the side chain thereof. Thereby, it tends to be excellent in compatibility with the photocurable compound (B).

In General Formula (1), in a case where R¹ to R⁴ are each a fluorine-containing group, specific examples of the fluorine-containing group include fluorine; an alkyl group having 1 to 10 carbon atoms in which some or all of the hydrogens in the alkyl group have been substituted with fluorine, such as a fluoromethyl group, a difluoromethyl group, a trifluoromethyl group, a trifluoroethyl group, a pentafluoroethyl group, a heptafluoropropyl group, a hexafluoroisopropyl group, a heptafluoroisopropyl group, a hexafluoro-2-methylisopropyl group, a perfluoro-2-methylisopropyl group, an n-perfluorobutyl group, an n-perfluoropentyl group, or a perfluorocyclopentyl group;

an alkoxy group having 1 to 10 carbon atoms in which some or all of the hydrogens in the alkoxy group have been substituted with fluorine, such as a fluoromethoxy group, a difluoromethoxy group, a trifluoromethoxy group, a trifluoroethoxy group, a pentafluoroethoxy group, a heptafluoropropoxy group, a hexafluoroisopropoxy group, a heptafluoroisopropoxy group, a hexafluoro-2-methylisopropoxy group, a perfluoro-2-methylisopropoxy group, an n-perfluorobutoxy group, an n-perfluoropentoxy group, or a perfluorocyclopentoxy group; and an alkoxyalkyl group having 2 to 10 carbon atoms in which some or all of the hydrogens in the alkoxyalkyl group have been substituted with fluorine, such as a fluoromethoxymethyl group, a difluoromethoxymethyl group, a trifluoromethoxymethyl group, a trifluoroethoxymethyl group, a pentafluoroethoxymethyl group, a heptafluoropropoxymethyl group, a hexafluoroisopropoxymethyl group, a heptafluoroisopropoxymethyl group, a hexafluoro-2-methylisopropoxymethyl group, a perfluoro-2-methylisopropoxymethyl group, an n-perfluorobutoxymethyl group, an n-perfluoropentoxymethyl group, or a perfluorocyclopentoxymethyl group.

In addition, R¹ to R⁴ may be bonded to each other to form a ring structure. For example, a ring such as perfluorocycloalkyl and perfluorocycloether via oxygen may be formed.

In a case where R¹ to R⁴ are not a fluorine-containing group, specific examples of R¹ to R⁴ include hydrogen; an alkyl group having 1 to 10 carbon atoms, such as a methyl group, an ethyl group, a propyl group, an isopropyl group, a 2-methylisopropyl group, an n-butyl group, an n-pentyl group, or a cyclopentyl group; an alkoxy group having 1 to 10 carbon atoms, such as a methoxy group, an ethoxy group, a propoxy group, a butoxy group, or a pentoxy group; and

an alkoxyalkyl group having 2 to 10 carbon atoms, such as a methoxymethyl group, an ethoxymethyl group, a propoxymethyl group, a butoxymethyl group, or a pentoxymethyl group.

R¹ to R⁴ in General Formula (1) are each preferably fluorine; or a fluoroalkyl group having 1 to 10 carbon atoms in which some or all of the hydrogens in the alkyl group have been substituted with fluorine, such as a fluoromethyl group, a difluoromethyl group, a trifluoromethyl group, a trifluoroethyl group, a pentafluoroethyl group, a heptafluoropropyl group, a hexafluoroisopropyl group, a heptafluoroisopropyl group, a hexafluoro-2-methylisopropyl group, a perfluoro-2-methylisopropyl group, an n-perfluorobutyl group, an n-perfluoropentyl group, or a perfluorocyclopentyl group.

The fluorine-containing cyclic olefin polymer (A) may be made up of only one type of structural unit represented by General Formula (1), or may be made up of two or more types of structural units in which at least one of R¹ to R⁴ in General Formula (1) is different from each other. In addition, the fluorine-containing cyclic olefin polymer (A) may be a polymer (copolymer) containing one or two or more types of structural units represented by General Formula (1) and a structural unit different from the structural unit represented by General Formula (1).

In the fluorine-containing cyclic olefin polymer (A), the content of the structural unit represented by General Formula (1) is usually 30% to 100% by mass, preferably 70% to 100% by mass, and more preferably 90% to 100% by mass, based on 100% by mass of the entire polymer.

Hereinafter, specific examples of the fluorine-containing cyclic olefin polymer (A) (preferably containing the structural unit represented by General Formula (1)) will be described, but the fluorine-containing cyclic olefin polymer (A) is not limited thereto.

Poly(1-fluoro-2-trifluoromethyl-3,5-cyclopentyleneethylene), poly(1-fluoro-1-trifluoromethyl-3,5-cyclopentyleneethylene), poly(1-methyl-1-fluoro-2-trifluoromethyl-3,5-cyclopentyleneethylene), poly(1,1-difluoro-2-trifluoromethyl-3,5-cyclopentyleneethylene), poly(1,2-difluoro-2-trifluoromethyl-3,5-cyclopentyleneethylene), poly(1-perfluoroethyl-3,5-cyclopentyleneethylene), poly(1,1-bis(trifluoromethyl)-3,5-cyclopentyleneethylene), poly(1,1,2-trifluoro-2-trifluoromethyl-3,5-cyclopentyleneethylene), poly(1,2-bis(trifluoromethyl)-3,5-cyclopentyleneethylene), poly(1-perfluoropropyl-3,5-cyclopentyleneethylene), poly(1-methyl-2-perfluoropropyl-3,5-cyclopentyleneethylene), poly(1-butyl-2-perfluoropropyl-3,5-cyclopentyleneethylene), poly(1-perfluoro-iso-propyl-3,5-cyclopentyleneethylene), poly(1-methyl-2-perfluoro-iso-propyl-3,5-cyclopentyleneethylene), poly(1,2-difluoro-1,2-bis(trifluoromethyl)-3,5-cyclopentyleneethylene), poly(1,1,2,2,3,3,3a,6a-octafluorocyclopentyl-4,6-cyclopentyleneethylene), poly(1,1,2,2,3,3,4,4,3a,7a-decafluorocyclohexyl-5,7-cyclopentyleneethylene), poly(1-perfluorobutyl-3,5-cyclopentyleneethylene), poly(1-perfluoro-iso-butyl-3,5-cyclopentyleneethylene), poly(1-perfluoro-tert-butyl-3,5-cyclopentyleneethylene), poly(1-methyl-2-perfluoro-iso-butyl-3,5-cyclopentyleneethylene), poly(1-butyl-2-perfluoro-iso-butyl-3,5-cyclopentyleneethylene), poly(1,2-difluoro-1-trifluoromethyl-2-perfluoroethyl-3,5-cyclopentyleneethylene, poly(1-(1-trifluoromethyl-2,2,3,3,4,4,5,5-octafluoro-cyclopentyl)-3,5-cyclopentyleneethylene), poly((1,1,2-trifluoro-2-perfluorobutyl)-3,5-cyclopentyleneethylene), poly(1,2-difluoro-1-trifluoromethyl-2-perfluorobutyl-3,5-cyclopentyleneethylene), poly(1-fluoro-1-perfluoroethyl-2,2-bis(trifluoromethyl)-3,5-cyclopentyleneethylene, poly(1,2-difluoro-1-perfluoropropanyl-2-trifluoromethyl-3,5-cyclopentyleneethylene), poly(1-perfluorohexyl-3,5-cyclopentyleneethylene), poly(1-methyl-2-perfluorohexyl-3,5-cyclopentyleneethylene), poly(1-butyl-2-perfluorohexyl-3,5-cyclopentyleneethylene), poly(1-hexyl-2-perfluorohexyl-3,5-cyclopentyleneethylene), poly(1-octyl)-2-perfluorohexyl-3,5-cyclopentyleneethylene), poly(1-perfluoroheptyl-3,5-cyclopentyleneethylene), poly(1-perfluorooctyl-3,5-cyclopentyleneethylene), poly(1-perfluorodecanyl-3,5-cyclopentyleneethylene), poly(1,1,2-trifluoro-perfluoropentyl-3,5-cyclopentyleneethylene), poly(1,2-difluoro-1-trifluoromethyl-2-perfluorobutyl-3,5-cyclopentyleneethylene), poly(1,1,2-trifluoro-perfluorohexyl-3,5-cyclopentyleneethylene), poly(1,2-difluoro-1-trifluoromethyl-2-perfluoropentyl-3,5-cyclopentyleneethylene), poly(1,2-bis(perfluorobutyl)-3, 5-cyclopentyleneethylene), poly(1,2-bis(perfluorohexyl)-3, 5-cyclopentyleneethylene), poly(1-methoxy-2-trifluoromethyl-3,5-cyclopentyleneethylene), poly(1-tert-butoxymethyl-2-trifluoromethyl-3,5-cyclopentyleneethylene), poly(1,1,3, 3,3a, 6a-hexafluorofuranyl-3,5-cyclopentyleneethylene), and the like.

In addition, the fluorine-containing cyclic olefin polymer (A) of the present embodiment may contain a structural unit represented by General Formula (2).

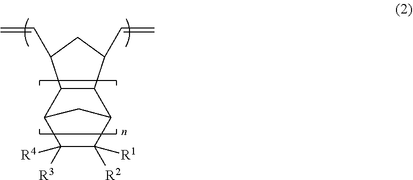

In General Formula (2), R¹ to R⁴ and n have the same definition as in General Formula (1).

The glass transition temperature of the fluorine-containing cyclic olefin polymer (A) as measured by differential scanning calorimetry is preferably 30° C. to250° C., more preferably50° C. to 200° C., and still more preferably 60° C. to 160° C.

In a case where the glass transition temperature is equal to or higher than the above-mentioned lower limit value, a fine concave-convex shape formed after releasing the mold can be maintained with high accuracy. In addition, in a case where the glass transition temperature is equal to or lower than the above-mentioned upper limit value, melt flow is easy so that the heat treatment temperature can be lowered, and yellowing of the resin layer or deterioration of the support can be suppressed.

For example, the weight average molecular weight (Mw) of the fluorine-containing cyclic olefin polymer (A) in terms of polystyrene measured by gel permeation chromatography (GPC) at a sample concentration of 3.0 to 9.0 mg/ml is preferably 5,000 to 1,000,000 and more preferably 10,000 to 300,000.

In a case where the weight average molecular weight (Mw) is within the above range, the solvent solubility of the fluorine-containing cyclic olefin polymer (A) and the fluidity during thermocompression molding are good.

The molecular weight distribution of the fluorine-containing cyclic olefin polymer (A) is preferably somewhat broad from the viewpoint of good heat moldability. The molecular weight distribution (Mw/Mn), which is the ratio of the weight average molecular weight (Mw) to the number average molecular weight (Mn), is preferably 1.0 to 5.0, more preferably 1.2 to 5.0, and still more preferably 1.4 to 3.0.

The photocurable resin layer 102 may contain only one type of the fluorine-containing cyclic olefin polymer (A), or may contain two or more types of the fluorine-containing cyclic olefin polymers (A).

The content of the fluorine-containing cyclic olefin polymer (A) in the photocurable resin layer 102 is preferably 1% to 80% by mass and more preferably 3% to 75% by mass based on the entire photocurable resin layer 102 (100% by mass).

Method for Producing Fluorine-Containing Cyclic Olefin Polymer (A)

The method for producing the fluorine-containing cyclic olefin polymer (A), more specifically, the method for producing a polymer containing the structural unit represented by General Formula (1) (polymerization method) will be described.

The fluorine-containing cyclic olefin polymer (A) can be produced, for example, in such a manner that a fluorine-containing cyclic olefin monomer represented by General Formula (3) is polymerized by a ring-opening metathesis polymerization catalyst to obtain a fluorine-containing cyclic olefin polymer (A) containing a structural unit represented by General Formula (2), and further, hydrogenating the olefin moiety of the main chain thereof to thereby produce the fluorine-containing cyclic olefin polymer (A) containing the structural unit represented by General Formula (1). More specifically, the fluorine-containing cyclic olefin polymer (A) can be produced according to the method described in paragraphs [0075] to [0099] of Pamphlet of International Publication No. WO 2011/024421.

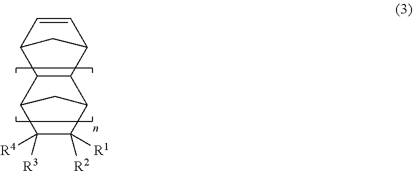

In General Formula (3), the definitions and specific examples of R¹ to R⁴ and n are the same as those in General Formula (1).

In producing the fluorine-containing cyclic olefin polymer (A), only one type of the fluorine-containing cyclic olefin monomer represented by General Formula (3) may be used, or two or more types of the fluorine-containing cyclic olefin monomers represented by General Formula (3) may be used.

In the fluorine-containing cyclic olefin polymer (A), the hydrogenation of the olefin moiety (the double bond portion of the main chain) of the polymer represented by General Formula (2) does not need to be carried out depending on the usage, usage environment, and conditions of the laminate of the present invention. On the other hand, in a case where there are restrictions on the usage, usage environment, and conditions, the hydrogenation ratio of the olefin moiety (the double bond portion of the main chain) of the polymer represented by General Formula (2) is preferably equal to or more than 50 mol %, more preferably equal to or more than 70 mol % and equal to or less than 100 mol %, and still more preferably equal to or more than 90 mol % and equal to or less than 100 mol %. In a case where the hydrogenation ratio is equal to or more than the above-mentioned lower limit value, oxidation of the olefin moiety and deterioration of light absorption can be suppressed, and heat resistance or weather resistance can be further improved. In addition, in a case of obtaining a transfer body in the imprint step, light sufficient to cure the photocurable compound (B) can be transmitted.

Photocurable Compound (B)

Examples of the photocurable compound (B) include a compound having a reactive double bond group and a cationically polymerizable ring-opening polymerizable compound, among which a cationically polymerizable ring-opening polymerizable compound (specifically, a compound containing a ring-opening polymerizable group such as an epoxy group or an oxetanyl group) is preferable.

The photocurable compound (B) may have one reactive group in one molecule or may have a plurality of reactive groups in one molecule, but a compound having two or more reactive groups is preferably used. The upper limit of the number of reactive groups in one molecule is not particularly limited, but is, for example, two, preferably four.

As the photocurable compound (B), only one type may be used, or two or more types may be used. In a case where two or more types are used, compounds having different numbers of reactive groups may be mixed and used at a certain ratio. In addition, a compound having a reactive double bond group and a cationically polymerizable ring-opening polymerizable compound may be mixed and used at a certain ratio.

The boiling point of the photocurable compound (B) measured at 1 atm is preferably equal to or higher than 150° C. and equal to or lower than 350° C., more preferably equal to or higher than 150° C. and equal to or lower than 330° C., and still more preferably equal to or higher than 150° C. and equal to or lower than 320° C.

In a case where two or more types of photocurable compounds (B) are used, preferably 50% by mass or more of the entire photocurable compound (B) has the above-mentioned boiling point, more preferably 75% by mass or more of the entire photocurable compound (B) has the above-mentioned boiling point, and still more preferably all (100% by mass) of the photocurable compound (B) have the above-mentioned boiling point.

By setting the boiling point of the photocurable compound (B) at 1 atm within the above range, temporal changes in the properties of the photocurable resin layer 102 due to volatilization of the photocurable compound (B) can be suppressed. Specifically, it is possible to produce a laminate that can prevent the deterioration of the embedding property at the time of carrying out nanoimprinting, can be stably stored for a long period of time, and can accurately transfer a fine concave-convex pattern having a certain dimension even in a case where it is used after storage. Note that the phrase “can be stably stored for a long period of time” means that the laminate can be “make ahead” and that cost reduction by mass production is possible.

By appropriately selecting the type and compositional ratio of the photocurable compound (B), a three-dimensional network structure can be efficiently formed inside and on the surface of the photocurable resin layer 102. This allows the resulting concave-convex structure to have high surface hardness.

Further, from another viewpoint, it is considered that, in a case where the photocurable compound (B) contains fluorine, effects such as further improving the releasability can be obtained.

Specific examples in a case where the photocurable compound (B) is a compound having a reactive double bond group include the following.

Olefins such as fluorodienes (CF₂═CFOCF₂CF₂CF═CF₂, CF₂═CFOCF₂CF (CF₃)CF═CF₂, CF₂═CFCF₂C(OH)(CF₃) CH₂CH═CH₂, CF₂═CFCF₂C(OH)(CF₃)CH═CH₂, CF₂═CFCF₂C(CF₃)(OCH₂OCH₃)CH₂CH═CH₂, CF₂═CFCH₂C(C(CF₃)₂OH)(CF₃)CH₂CH═CH₂, and the like); cyclic olefins such as norbornene and norbornadiene; alkyl vinyl ethers such as cyclohexylmethyl vinyl ether, isobutyl vinyl ether, cyclohexyl vinyl ether, and ethyl vinyl ether; vinyl esters such as vinyl acetate; (meth)acrylic acids and derivatives thereof or fluorine-containing acrylates thereof such as (meth)acrylic acid, phenoxyethyl acrylate, benzyl acrylate, stearyl acrylate, lauryl acrylate, 2-ethylhexyl acrylate, allyl acrylate, 1,3-butanediol diacrylate, 1,4-butanediol diacrylate, 1,6-hexanediol diacrylate, trimethylol propane triacrylate, pentaerythritol triacrylate, dipentaerythritol hexaacrylate, ethoxyethyl acrylate, methoxyethyl acrylate, glycidyl acrylate, tetrahydrofurfuryl acrylate, diethylene glycol diacrylate, neopentyl glycol diacrylate, polyoxyethylene glycol diacrylate, tripropylene glycol diacrylate, 2-hydroxyethyl acrylate, 2-hydroxypropyl acrylate, 4-hydroxybutyl vinyl ether, N,N-diethylaminoethyl acrylate, N,N-dimethylaminoethyl acrylate, N-vinylpyrrolidone, and dimethyl aminoethyl methacrylate; and the like.

Among the photocurable compounds (B), examples of the cationically polymerizable ring-opening polymerizable compound, which is preferable from the viewpoint of long-term storage stability and compatibility with the fluorine-containing cyclic olefin polymer (A), include the following.

Epoxy compounds including alicyclic epoxy resins such as 1,7-octadiene diepoxide, 1-epoxydecane, cyclohexene epoxide, dicyclopentadiene oxide, limonene dioxide, 4-vinylcyclohexene dioxide, 3,4-epoxycyclohexylmethyl-3′,4′-epoxycyclohexanecarboxylate, di(3,4-epoxycyclohexyl)adipate, (3,4-epoxycyclohexyl)methyl alcohol, (3,4-epoxy-6-methylcyclohexyl)methyl-3,4-epoxy-6-methylcyclohexa necarboxylate, ethylene 1,2-di(3,4-epoxycyclohexanecarboxylic acid) ester, (3,4-epoxycyclohexyl)ethyltrimethoxysilane, 2-ethylhexyl glycidyl ether, phenyl glycidyl ether, dicyclohexyl-3,3′-diepoxide, a bisphenol A type epoxy resin, a halogenated bisphenol A type epoxy resin, a bisphenol F type epoxy resin, an o-, m-, or p-cresol novolak type epoxy resin, a phenol novolak type epoxy resin, a polyglycidyl ether of a polyhydric alcohol, and 3,4-epoxycyclohexenylmethyl-3′,4′-epoxycyclohexenecarboxylate, and epoxy compounds such as glycidyl ether of hydrogenated bisphenol A; oxetane compounds such as compounds having one oxetanyl group, for example, 3-methyl-3-(butoxymethyl)oxetane, 3-methyl-3-(pentyloxymethyl)oxetane, 3-methyl-3-(hexyloxymethyl)oxetane, 3-methyl-3-(2-ethylhexyloxymethyl)oxetane, 3-methyl-3-(octyloxymethyl)oxetane, 3-methyl-3-(decanoloxymethyl)oxetane, 3-methyl-3-(dodecanoloxymethyl)oxetane, 3-methyl-3-(phenoxymethyl)oxetane, 3-ethyl-3-(butoxymethyl)oxetane, 3-ethyl-3-(pentyloxymethyl)oxetane, 3-ethyl-3-(hexyloxymethyl)oxetane, 3-ethyl-3-(2-ethylhexyloxymethyl)oxetane, 3-ethyl-3-(octyloxymethyl)oxetane, 3-ethyl-3-(decanoloxymethyl)oxetane, 3-ethyl-3-(dodecanoloxymethyl)oxetane, 3-(cyclohexyloxymethyl)oxetane, 3-methyl-3-(cyclohexyloxymethyl)oxetane, 3-ethyl-3-(cyclohexyloxymethyl)oxetane, 3-ethyl-3-(phenoxymethyl)oxetane, 3,3-dimethyloxetane, 3-hydroxymethyloxetane, 3-methyl-3-hydroxymethyloxetane, 3-ethyl-3-hydroxymethyloxetane, 3-ethyl-3-phenoxymethyloxetane, 3-n-propyl-3-hydroxymethyloxetane, 3-isopropyl-3-hydroxymethyloxetane, 3-n-butyl-3-hydroxymethyloxetane, 3-isobutyl-3-hydroxymethyloxetane, 3-sec-butyl-3-hydroxymethyloxetane, 3-tert-butyl-3-hydroxymethyloxetane, and 3-ethyl-3-(2-ethylhexyl)oxetane, and compounds having two or more oxetanyl groups, for example, bis(3-ethyl-3-oxetanylmethyl)ether, 1,2-bis[(3-ethyl-3-oxetanylmethoxy)]ethane, 1,3-bis[(3-ethyl-3-oxetanylmethoxy)]propane, 1,3-bis[(3-ethyl-3-oxetanylmethoxy)]-2,2-dimethyl-propane, 1,4-bis(3-ethyl-3-oxetanylmethoxy)butane, 1,6-bis(3-ethyl-3-oxetanylmethoxy)hexane, 1,4-bis[(3-methyl-3-oxetanyl)methoxy]benzene, 1,3-bis[(3-methyl-3-oxetanyl)methoxy]benzene, 1,4-bis{[(3-methyl-3-oxetanyl)methoxy]methyl}benzene, 1,4-bis{[(3-methyl-3-oxetanyl)methoxy]methyl}cyclohexane, 4,4′-bis{[(3-methyl-3-oxetanyl)methoxy]methyl}biphenyl, 4,4′-bis{[(3-methyl-3-oxetanyl)methoxy]methyl}bicyclohexane, 2,3-bis[(3-methyl-3-oxetanyl)methoxy]bicyclo[2.2.1]heptane, 2,5-bis[(3-methyl-3-oxetanyl)methoxy]bicyclo[2.2.1]heptane, 2,6-bis[(3-methyl-3-oxetanyl)methoxy]bicyclo[2.2.1]heptane, 1,4-bis[(3-ethyl-3-oxetanyl)methoxy]benzene, 1,3-bis[(3-ethyl-3-oxetanyl)methoxy]benzene, 1,4-bis{[(3-ethyl-3-oxetanyl)methoxy]methyl}benzene, 1,4-bis{[(3-ethyl-3-oxetanyl)methoxy]methyl}cyclohexane, 4,4′-bis{[(3-ethyl-3-oxetanyl)methoxy]methyl}biphenyl, 4,4′-bis{[(3-ethyl-3-oxetanyl)methoxy]methyl}bicyclohexane, 2,3-bis[(3-ethyl-3-oxetanyl)methoxy]bicyclo[2.2.1]heptane, 2,5-bis[(3-ethyl-3-oxetanyl)methoxy]bicyclo[2.2.1]heptane, and 2,6-bis[(3-ethyl-3-oxetanyl)methoxy]bicyclo[2.2.1]heptane; and the like.

The content of the photocurable compound (B) in the photocurable resin layer 102 is preferably 15% to 98% by mass and more preferably 20% to 95% by mass based on the entire photocurable resin layer 102 (100% by mass).

In addition, the mass ratio ((A)/(B)) of the content of the fluorine-containing cyclic olefin polymer (A) to the content of the photocurable compound (B) in the photocurable resin layer 102 is preferably 1/99 to 80/20, more preferably 5/95 to 75/25, and still more preferably 30/70 to 70/30. It is considered that, in a case where the mass ratio ((A)/(B)) is within this range, effects such as good releasability (ease of peeling of the protective film layer 103) due to the fluorine-containing cyclic olefin polymer (A) and good releasability in a case of forming a concave or convex structure can be sufficiently obtained. In addition, the viscosity of the photocurable resin layer 102 at the time of pressing the mold can be made appropriate, and the embedding accuracy can be improved. As a sum of these effects, the dimensional accuracy of the fine concave-convex pattern can be further increased, and a good concave-convex structure can be obtained.

Photocuring Initiator (C)

Examples of the photocuring initiator (C) include a photoradical initiator that generates a radical upon irradiation with light, and a photocationic initiator that generates a cation upon irradiation with light.

Among the photocuring initiators (C), examples of the photoradical initiator that generates a radical upon irradiation with light include acetophenones such as acetophenone, p-tert-butyltrichloroacetophenone, chloroacetophenone, 2,2-diethoxyacetophenone, hydroxyacetophenone, 2,2-dimethoxy-2′-phenylacetophenone, 2-aminoacetophenone, and dialkylaminoacetophenone; benzoins such as benzoin, benzoin methyl ether, benzoin ethyl ether, benzoin isopropyl ether, benzoin isobutyl ether, 1-hydroxycyclohexylphenyl ketone, 2-hydroxy-2-methyl-1-phenyl-2-methylpropan-1-one, and 1-(4-isopropylphenyl)-2-hydroxy-2-methylpropan-1-one; benzophenones such as benzophenone, benzoyl benzoate, methyl benzoyl benzoate, methyl-o-benzoyl benzoate, 4-phenylbenzophenone, hydroxybenzophenone, hydroxypropylbenzophenone, acrylbenzophenone, and 4,4′-bis(dimethylamino)benzophenone; thioxanthones such as thioxanthone, 2-chlorothioxanthone, 2-methylthioxanthone, diethylthioxanthone, and dimethylthioxanthone; fluorine-based peroxides such as perfluoro(tert-butyl peroxide) and perfluorobenzoyl peroxide; a-acyl oxime ester, benzyl-(o-ethoxycarbonyl)-α-monooxime, acylphosphine oxide, glyoxyester, 3-ketocoumarin, 2-ethylanthraquinone, camphorquinone, tetramethylthiuram sulfide, azobisisobutyronitrile, benzoyl peroxide, dialkyl peroxide, and tert-butylperoxy pivalate. These compounds often exhibit their functions mainly in the UV region where the light wavelength is equal to or longer than 200 nm and equal to or shorter than 400 nm.

Examples of the preferably used photoradical initiator include IRGACURE 651 (manufactured by Ciba Specialty Chemicals Corporation), IRGACURE 184 (manufactured by Ciba Specialty Chemicals Corporation), DAROCUR 1173 (manufactured by Ciba Specialty Chemicals Corporation), benzophenone, 4-phenylbenzophenone, IRGACURE 500 (manufactured by Ciba Specialty Chemicals Corporation), IRGACURE 2959 (manufactured by Ciba Specialty Chemicals Corporation) IRGACURE 127 (manufactured by Ciba Specialty Chemicals Corporation), IRGACURE 907 (manufactured by Ciba Specialty Chemicals Corporation), IRGACURE 369 (manufactured by Ciba Specialty Chemicals Corporation), IRGACURE 1300 (manufactured by Ciba Specialty Chemicals Corporation), IRGACURE 819 (manufactured by Ciba Specialty Chemicals Corporation), IRGACURE 1800 (manufactured by Ciba Specialty Chemicals Corporation), DAROCUR TPO (manufactured by Ciba Specialty Chemicals Corporation), DAROCUR 4265 (manufactured by Ciba Specialty Chemicals Corporation), IRGACURE OXE01 (manufactured by Ciba Specialty Chemicals Corporation), IRGACURE OXE02 (manufactured by Ciba Specialty Chemicals Corporation), ESACURE-KT55 (manufactured by Lamberti S.p.A.), ESACURE-KIP150 (manufactured by Lamberti S.p.A.), ESACURE-KIP100F (manufactured by Lamberti S.p.A.), ESACURE-KT37 (manufactured by Lamberti S.p.A.), ESACURE-KTO46 (manufactured by Lamberti S.p.A.), ESACURE-1001 M (manufactured by Lamberti S.p.A.), ESACURE-KIP/EM (manufactured by Lamberti S.p.A.), ESACURE-DP250 (manufactured by Lamberti S.p.A.), ESACURE-KB1 (manufactured by Lamberti S.p.A.), and 2,4-diethylthioxanthone. Among these, examples of the more preferably used photoradical polymerization initiator include IRGACURE 184 (manufactured by Ciba Specialty Chemicals Corporation), DAROCUR 1173 (manufactured by Ciba Specialty Chemicals Corporation), IRGACURE 500 (manufactured by Ciba Specialty Chemicals Corporation), IRGACURE 819 (manufactured by Ciba Specialty Chemicals Corporation), DAROCUR TPO (manufactured by Ciba Specialty Chemicals Corporation), ESACURE-KIP100F (manufactured by Lamberti S.p.A.), ESACURE-KT37 (manufactured by Lamberti S.p.A.), and ESACURE-KTO46 (manufactured by Lamberti S.p.A.).

Among the photocuring initiators (C), the photocationic initiator that generates a cation upon irradiation with light is not particularly limited as long as it is a compound that initiates cationic polymerization of the above-mentioned ring-opening polymerizable compounds that can be cationically polymerized upon irradiation with light. Preferred is a compound that releases a Lewis acid through a photoreaction, such as an onium salt of an onium cation-a counter anion thereof. These compounds often exhibit their functions mainly in the UV region where the light wavelength is equal to or longer than 200 nm and equal to or shorter than 400 nm.

Examples of the onium cation include diphenyliodonium, 4-methoxydiphenyliodonium, bis (4-methylphenyl) iodonium, bis(4-tert-butylphenyl)iodonium, bis(dodecylphenyl)iodonium, triphenylsulfonium, diphenyl-4-thiophenoxyphenylsulfonium, bis[4-(diphenylsulfonio)-phenyl]sulfide, bis[4-(di(4-(2-hydroxyethyl)phenyl)sulfonio)-phenyl]sulfide, and η5-2,4-(cyclopentadienyl)[1,2,3,4,5,6-η-(methylethyl)benzene]-iron (1+). Further, a perchlorate ion, a trifluoromethanesulfonate ion, a toluenesulfonate ion, a trinitrotoluenesulfonate ion, and the like can be mentioned in addition to the onium cation.

On the other hand, examples of the counter anion include tetrafluoroborate, hexafluorophosphate, hexafluoroantimonate, hexafluoroarsenate, hexachloroantimonate, tetra(fluorophenyl)borate, tetra(difluorophenyl)borate, tetra(trifluorophenyl)borate, tetra(tetrafluorophenyl)borate, tetra(pentafluorophenyl)borate, tetra(perfluorophenyl)borate, tetra(trifluoromethylphenyl)borate, and tetra(di(trifluoromethyl)phenyl)borate.

Specific examples of the more preferably used photocationic initiator include IRGACURE 250 (manufactured by Ciba Specialty Chemicals Corporation), IRGACURE 784 (manufactured by Ciba Specialty Chemicals Corporation), ESACURE-1064 (manufactured by Lamberti S.p.A.), CYRAUREUVI6990 (manufactured by Union Carbide Japan K.K.), ADEKA OPTOMER SP-172 (manufactured by Adeka Corporation), ADEKA OPTOMER SP-170 (manufactured by Adeka Corporation), ADEKA OPTOMER SP-152 (manufactured by Adeka Corporation), ADEKA OPTOMER SP-150 (manufactured by Adeka Corporation), CPI-210K (manufactured by San-Apro Ltd.), CPI-210S (manufactured by San-Apro Ltd.), and CPI-100P (manufactured by San-Apro Ltd.).

The photocurable resin layer 102 may contain only one photocuring initiator (C), or may contain two or more photocuring initiators (C).

The content of the photocuring initiator (C) in the photocurable resin layer 102 is preferably 0.1% to 10.0% by mass and more preferably 1.0% to 7.0% by mass based on the entire photocurable resin layer 102 (100% by mass).

Other Components

The photocurable resin layer 102 may contain components other than the above-mentioned (A) to (C). For example, a modifier such as an anti-aging agent, a leveling agent, a wettability improver, a surfactant, or a plasticizer, a stabilizer such as an ultraviolet absorber, a preservative, or an antimicrobial agent, a photosensitizing agent, a silane coupling agent, and the like may be contained in the photocurable resin layer 102. For example, a plasticizer is preferable because it maybe useful for adjusting the viscosity in addition to providing the above-mentioned effects.

Thickness of Photocurable Resin Layer 102

The thickness of the photocurable resin layer 102 is not particularly limited, but is preferably 0.05 to 1000 μm, more preferably 0.05 to 500 μm, and still more preferably 0.05 to 250 μm. The thickness may be appropriately adjusted depending on the depth of the concavity-convexity of the mold used, the use of the finally obtained concave-convex structure, and the like.

(Protective Film Layer 103)

The protective film layer 103 is used to protect the photocurable resin layer 102 and protects the surface of the photocurable resin layer 102 that is exposed to the atmosphere until the concave-convex structure is produced.

It is preferable that the protective film layer 103 is easily peelable. In other words, it is preferable in the laminate according to the present embodiment that the protective film layer 103 can be easily peeled off from the photocurable resin layer 102 without requiring any special treatment with, for example, a peeling chemical. In addition, at the time of this peeling, it is preferable that the photocurable resin layer 102 hardly adheres or remains on the protective film layer 103.

As described above, in the laminate according to the present embodiment, since the photocurable resin layer 102 contains the fluorine-containing cyclic olefin polymer (A), the peelability of the protective film layer is considered to be originally good. However, concerns such as surface roughness such as stringing and zipping at the time of peeling can be further reduced by appropriately selecting the material, surface properties, surface physical properties, and the like of the protective film layer 103. In addition, it is preferable that the components contained in the protective film layer 103 are hardly eluted into the photocurable resin layer 102.

Specific examples of the protective film layer 103 include a film obtained by processing a resin such as polyethylene, polyester, polyimide, polycycloolefin, poly(meth)acrylate, or polyethylene terephthalate, and a film based on a sheet-like processed product of such a resin. Among them, a polyester film is preferable as the material of the protective film layer 103.

The protective film layer 103 may be kneaded with a silicon compound or a fluorine compound for the purpose of improving an easy peeling function. In addition, the protective film layer 103 may be a metal thin film made of an inorganic material.

As another viewpoint, in a case where it is desired to ensure long-term storage stability of the laminate, it is conceivable to use an opaque (light-shielding) material as the protective film layer 103 for the purpose of maintaining the properties of the photocurable compound (B).

The thickness of the protective film layer 103 is not particularly limited, but is preferably 1 to 1000 μm and more preferably 10 to 500 μm from the viewpoint of easy peelability.

In a continuous method such as roll-to-roll processing, or in other uses, it is preferable that the protective film layer 103 does not deform or break due to a pressing force such as winding stress or defoaming. The possibility of deformation or breakage can be reduced by appropriately adjusting the thickness.

From the viewpoint of storage stability and the like, the laminate is preferably placed in a dark place during storage.

<Method for Producing Laminate>

The method for producing a laminate according to the present embodiment is not particularly limited. The laminate according to the present embodiment can be produced by, for example, steps including a step of forming a photocurable resin layer 102 containing a fluorine-containing cyclic olefin polymer (A), a photocurable compound (B) and a photocuring initiator (C) on a surface of a base material layer 101 (photocurable resin layer forming step); and a step of forming a protective film layer 103 on the surface of the photocurable resin layer 102 (protective film layer forming step).

The specific method of the photocurable resin layer forming step is not particularly limited, but typically, the photocurable resin layer forming step can be carried out by dissolving or dispersing the fluorine-containing cyclic olefin polymer (A), the photocurable compound (B), the photocuring initiator (C), and, if necessary, other components in an appropriate solvent (typically, an organic solvent) to prepare a coating liquid, applying the coating liquid onto the surface of the base material layer 101, and then drying the solvent.

At this time, the solvent (organic solvent) for preparing the coating liquid is not particularly limited. Examples of the solvent include fluorine-containing aromatic hydrocarbons such as meta-xylene hexafluoride, benzotrifluoride, fluorobenzene, difluorobenzene, hexafluorobenzene, trifluoromethylbenzene, bis(trifluoromethyl)benzene, and meta-xylene hexafluoride; fluorine-containing aliphatic hydrocarbons such as perfluorohexane and perfluorooctane; fluorine-containing aliphatic cyclic hydrocarbons such as perfluorocyclodecalin; fluorine-containing ethers such as perfluoro-2-butyltetrahydrofuran; halogenated hydrocarbons such as chloroform, chlorobenzene, and trichlorobenzene; ethers such as tetrahydrofuran, dibutyl ether, 1,2-dimethoxyethane, dioxane, propylene glycol monomethyl ether (referred to as PGMEA), dipropylene glycol monomethyl ether, and propylene glycol monomethyl ether acetate; esters such as ethyl acetate, propyl acetate, and butyl acetate; ketones such as methyl ethyl ketone, methyl isobutyl ketone, and cyclohexanone; and alcohols such as methanol, ethanol, isopropyl alcohol, 2-methoxyethanol, and 3-methoxypropanol. Any of these may be selected in consideration of solubility, film forming property, and the like.

The solvents for preparing the coating liquid may be used alone or in combination of two or more thereof.

The solvent for preparing the coating liquid is used in such an amount that the solid content concentration of the coating liquid (the concentration of components other than the solvent) is typically 1% to 90% by mass and preferably 5% to 80% by mass. Note that it is not essential to use a solvent.

A known method can be applied to the coating method. Examples of the known coating method include table coating, spin coating, dip coating, die coating, spray coating, bar coating, roll coating, curtain flow coating, slit coating, and inkjet coating.

In addition, a baking (heating) step may be provided after the application, if necessary, for the purpose of removing the solvent. Various conditions such as baking temperature and time may be appropriately set in consideration of the coating thickness, the process style, and the productivity. The baking temperature and time are selected in a temperature range of preferably 20° C. to 200° C., more preferably 20° C. to 180° C., for a time of preferably 0.5 to 30 minutes, more preferably 0.5 to 20 minutes.

The baking method may be any method such as directly heating with a heating plate or the like, passing through a hot air stove, or using an infrared heater.

The specific method of the protective film layer forming step is not particularly limited as long as it is a method of bring the protective film layer into close contact such that foreign matter such as dust is not be caught. Typically, there is a method in which the protective film layer 103 is brought into close contact on the photocurable resin layer 102 formed in the above-mentioned photocurable resin layer forming step.

The formation of the protective film layer 103 may be a batch method or a roll-to-roll continuous method. In addition, it is preferable that bubbles are removed by applying a pressure in a case where the photocurable resin layer 102 and the protective film layer 103 are in contact with each other to bring them close contact with each other. For this purpose, a hand roller may be pressed. In a case of a roll-to-roll continuous method, bubbles may be removed by bringing the protective film layer 103 sent from a feed roll into close contact with the photocurable resin layer 102 while applying a pressure with a nip roll or the like.

As another method, a coating liquid containing a silicon compound, a fluorine compound, or the like may be applied onto the surface of the photocurable resin layer 102 by a method such as spin coating or slit coating, and then dried to form the protective film layer 103. As still another method, a coating liquid containing a silicon compound, a fluorine compound, or the like may be applied onto the surface of the metal thin film by a method such as spin coating or slit coating.

Although the embodiments of the present invention have been described above, these embodiments are only examples of the present invention, and various configurations other than the above-mentioned configurations can be adopted. In addition, the present invention is not limited to the above-mentioned embodiments, and includes modifications and improvements as long as the object of the present invention can be achieved.

### EXAMPLES

Embodiments of the present invention will be described with reference to examples. The present invention is not limited to the examples.

First, the method for evaluating the synthesized polymer, the mold used for the evaluation, the production procedure of the concave-convex structure, and the method for evaluating the dimensional accuracy will be described below.

[Weight Average Molecular Weight (Mw) and Molecular Weight Distribution (Mw/Mn)]

Under the following conditions, the weight average molecular weight (Mw) and the number average molecular weight (Mn) of the polymer dissolved in tetrahydrofuran (THF) were measured using gel permeation chromatography (GPC) by the calibration of the molecular weights thereof with a polystyrene standard.
Detector: RI-2031 and 875-UV manufactured by JASCO Corporation
Columns connected in series: Shodex K-806M, 804, 803, and 802.5
Column temperature: 40° C., flow rate: 1.0 ml/min, sample concentration: 3.0 to 9.0 mg/ml

[Hydrogenation Ratio of Fluorine-Containing Cyclic Olefin Polymer (A)]

The powder of the ring-opening metathesis polymer subjected to the hydrogenation reaction was dissolved in deuterated tetrahydrofuran. From this, an integrated value of an absorption spectrum derived from hydrogen bonded to the double bond carbon of the main chain at δ=4.5 to 7.0 ppm was obtained by 270 MHz-¹H-NMR measurement, and a hydrogenation ratio was calculated from the integrated value.

[Glass Transition Temperature]

The measurement sample was heated at a heating rate of 10° C./min in a nitrogen atmosphere using an apparatus “DSC-50” manufactured by Shimadzu Corporation. At this time, an intersection between the baseline and the tangent at an inflection point was taken as the glass transition temperature.

[Mold Used (Equivalent to Mother Mold)]

A quartz mold having a pattern of linear lines (convex portions) and spaces (concave portions) was used.

Specifically, in a case where an equally spaced distance between the convex portions (a width of the concave portion) is L₀1, a width of the convex portion is L₀2, and a height of the convex portion is L₀3, a mold in which L₀1=250 nm, L₀2=250 nm, and L₀3=500 nm was used.

[Procedure for Producing Concave-Convex Structure]

First, a protective film of a three-layered laminate (which was stored at room temperature (23° C.) for 1 hour in a dark place after the production) produced in Examples described later was peeled off to expose a photocurable resin layer.

Next, the exposed photocurable resin layer was pressed against the pattern surface of the quartz mold at a pressure of 0.2 MPa.

While maintaining this pressure, light irradiation was carried out to cure the photocurable resin layer. Specifically, using a nanoimprint apparatus X-100U manufactured by SCIVAX Corporation, ultraviolet light having a wavelength of 365 nm was irradiated from the back of the quartz mold using a high-brightness LED as a light source to cure the photocurable resin layer.

After curing by light irradiation, a two-layered laminate in which the photocurable resin layer was cured was peeled off from the quartz mold to obtain a concave-convex structure.

[Evaluation of Dimensional Accuracy]

The pattern of the concave-convex structure obtained in the section [Procedure for producing concave-convex structure] was observed. A scanning electron microscope JSM-6701F (hereinafter, referred to as SEM) manufactured by JASCO Corporation was used for observation of the line (convex portion), space (concave portion) and cross section, and measurement of the film thickness.

In the cross-sectional micrograph of the SEM, any three places were measured for a width L1 of the convex portion, a width L2 of the concave portion, and a height L3 of the convex portion schematically shown in FIG. 2. As for L1 and L2, the measurement was carried out using a half of the upper surface of the convex portion (the height of the convex portion) from the upper surface of the concave portion as a measurement reference position.

The values closer to 250 nm for L1 and L2 and the value closer to 500 nm for L3 indicate that the dimensional accuracy is better.

[Evaluation of Dimensional Accuracy of Laminate with Temporal Changes]

In order to evaluate the dimensional accuracy of the laminate with temporal changes, a sample in which the produced laminate was stored at room temperature (23° C.) for 1 day and a sample in which the produced laminate was stored at room temperature (23° C.) for 7 days were prepared, and average values of L1, L2, and L3 were calculated in the same manner as described above.

Next, the average value of each dimension of the concave-convex structure formed of the laminate after a storage time of 1 day and 7 days was divided by the average value of each dimension of the concave-convex structure formed of the laminate having a storage time of 1 hour, thereby calculating the dimensional change of the laminate.

Specifically, as for the width (L1) of the convex portion, the average values of the widths (L1) of the convex portions in a case where imprinting was carried out in the above manner using laminates having a storage period of 1 hour, 1 day, and 7 days were defined as L1 (1 hour), L1 (1 day) and L1 (7 days), respectively, and then the dimensional accuracy L1ₑᵣ of the laminate after 1 day and 7 days was calculated by the following equation.

1 day later: L1ₑᵣ (1 day)=L1 (1 day)/L1 (1 hour)

7 days later: L1ₑᵣ (7 days)=L1 (7 days)/L1 (1 hour)

The dimensional accuracy (L2, and L3,) was similarly calculated for the width (L2) of the concave portion and the height (L3) of the convex portion. That is, the average value of each dimension of the concave-convex structure formed of the laminate having a storage time of 1 day or 7 days was divided by the average value of each dimension of the concave-convex structure formed of the laminate having a storage time of 1 hour, thereby obtaining L2ₑᵣ (1 day), L2ₑᵣ (7 days), L3ₑᵣ (1 day), and L3ₑᵣ (7 days).

The case where all of the calculated dimensional accuracy was in the range of 0.9 to 1.1 was marked with “∘” indicating good storage stability, and the other case was marked with “×”.

Hereinafter, a production example of a laminate, a synthesis example of a fluorine-containing cyclic olefin polymer therefor, a preparation example of a coating liquid, and the like will be described.

### Example 1

### Synthesis of Fluorine-containing Cyclic Olefin Polymer, Preparation of Coating Liquid for Forming Photocurable Resin Layer, and Production of Laminate

A solution of Mo (N-2, 6-Prⁱ₂C₆H₃) (CHCMe₂Ph) (OBu^{t})₂ (50 mg) in tetrahydrofuran was added to a solution of 5,5, 6-trifluoro-6-(trifluoromethyl)bicyclo[2.2.1]hept-2-ene (100 g) and 1-hexene (0.298 mg) in tetrahydrofuran, and then ring-opening metathesis polymerization was carried out at 70° C. The olefin moiety of the resulting polymer was subjected to a hydrogenation reaction with palladium alumina (5 g) at 160° C. to obtain a solution of poly(1,1,2-trifluoro-2-trifluoromethyl-3,5-cyclopentyleneethylene) in tetrahydrofuran.

The resulting solution was filtered under pressure through a filter having a pore diameter of 5 μm to remove palladium alumina. Next, the resulting solution was added to methanol, and a white polymer was separated by filtration and then dried to obtain 99 g of a polymer 1 as a fluorine-containing cyclic olefin polymer.

The resulting polymer 1 contained the structural unit represented by General Formula (1) described above. In addition, the polymer 1 had a hydrogenation ratio of 100 mol %, a weight average molecular weight (Mw) of 70,000, a molecular weight distribution (Mw/Mn) of 1.71, and a glass transition temperature of 107° C.

Next, a solution was prepared in which 13 g of a mixture [mass ratio ((A)/(B))=60.6/39.4] of bis(3-ethyl-3-oxetanylmethyl)ether having a boiling point of 280° C. under atmospheric pressure and 1,7-octadiene diepoxide having a boiling point of 240° C. under atmospheric pressure at a mass ratio of 2/8 as the photocurable compound (B) and 0.65 g of CPI-210K (trade name, manufactured by San-Apro Ltd.) as the photocuring initiator (C) were added to 100 g of a cyclohexanone solution in which the polymer 1 was dissolved at a concentration of 20% by mass.

Then, this solution was filtered under pressure through a filter having a pore diameter of 1 μm, and further filtered through a filter having a pore diameter of 0.1 μm to prepare a resin composition 1 (coating liquid).

This resin composition 1 was applied to a PET film having a size of 10 cm×10 cm (LUMIRROR (registered trademark) U34, manufactured by Toray Industries, Inc.) using a bar coater with a rod number 9 to form a liquid film having a uniform thickness. Next, baking was carried out for 120 seconds using a hot plate heated to 50° C. to remove the solvent. At this time, the measured film thickness of the resin composition 1 after removing the solvent (drying) was 5 μm.

Next, a Tohcello separator TMSPT18 (polyester-based film, thickness: 50 μm, manufactured by Mitsui Chemicals Tohcello, Inc.) as a protective film was brought into contact with the air surface of the resin composition 1 after removing the solvent (drying), and was then brought into close contact while removing bubbles with a hand roller. Thus, a laminate 1 having a three-layered structure was produced. The appearance of the obtained laminate 1 did not show any problems such as adhesion of dust, bite of bubbles, and fluctuation of the surface.

### Example 2

### Preparation of Coating Liquid for Forming Photocurable Resin Layer and Production Of Laminate

10 g of the polymer 1 synthesized in Example 1 and 90 g of a photocurable compound (a mixture of bis(3-ethyl-3-oxetanylmethyl)ether having a boiling point of 280° C. and 2-ethylhexylglycidyl ether having a boiling point of 260° C. (mass ratio of 5/5)) were uniformly mixed to prepare a liquid mixture.

Next, 4.5 g of CPI-100P (trade name, manufactured by San-Apro Ltd.) as the photocuring initiator (C) was added to the above mixture to prepare a liquid composition.

This composition was filtered under pressure through a filter having a pore diameter of 1 μm, and further filtered through a filter having a pore diameter of 0.1 μm to prepare a resin composition 2.

The production of the laminate was carried out in the same manner as in Example 1, except that the baking step on the hot plate was omitted, and thereby a laminate 2 was produced. The film thickness of the resin composition 2 measured immediately after coating on a PET film was 10 μm.

### Example 3

### Preparation of Coating Liquid for Forming Photocurable Resin Layer and Production of Laminate

Using the resin composition 1 prepared in Example 1, a laminate 3 was produced in the same manner as in Example 1, except that the substrate on which the resin composition 1 was applied was changed to quartz having a size of 5 cm×5 cm. At this time, the film thickness of the resin composition 1 measured immediately after coating on the quartz was 5 μm.

### Example 4

### Synthesis of Fluorine-Containing Cyclic Olefin Polymer, Preparation of Coating Liquid for Forming Photocurable Resin Layer, and Production of Laminate

49 g of a polymer 2[poly(1,2-difluoro-1-trifluoromethyl-2-perfluoroethyl-3,5-cyclopentyleneethylene)] as the fluorine-containing cyclic olefin polymer was obtained in the same manner as in Example 1, except that the monomer was changed to 5,6-difluoro-5-trifluoromethyl-6-perfluoroethylbicyclo[2.2.1]hept-2-ene (50 g).

The resulting polymer 2 contained the structural unit represented by General Formula (1) described above. The polymer 2 had a hydrogenation ratio of 100 mol %, a weight average molecular weight (Mw) of 80,000, a molecular weight distribution (Mw/Mn) of 1.52, and a glass transition temperature of 110° C.

Next, a resin composition 3 was prepared in the same manner as in Example 1, except that the fluorine-containing cyclic olefin polymer was changed to the polymer 2.

Then, using this resin composition 3, a laminate 4 was produced in the same manner as in Example 1. At this time, the film thickness of the resin composition 3 measured immediately after coating on a PET film was 7 μm.

### Example 5

### Preparation of Coating Liquid for Forming Photocurable Resin Layer and Production of Laminate

A resin composition 4 was prepared in the same manner as in Example 1, except that the photocurable compound (B) was changed to methyl glycidyl ether having a boiling point of 116° C. at 1 atm.

Next, a laminate 5 was produced in the same manner as in Example 1. At this time, the film thickness of the resin composition 4 measured immediately after coating on a PET film was 5 μm.

### Example 6

### Synthesis of Fluorine-Containing Cyclic Olefin Polymer, Preparation of Coating Liquid for Forming Photocurable Resin Layer, and Production of Laminate

First, ring-opening metathesis polymerization was carried out in the same manner as in Example 1.

Then, a solution of the resulting unhydrogenated polymer of poly(1,1,2-trifluoro-2-trifluoromethyl-3,5-cyclopentyleneethylene) in tetrahydrofuran was added to hexane, and a pale yellow polymer was filtered off and dried to give 99 g of a polymer 3 as the fluorine-containing cyclic olefin polymer.

The resulting polymer 3 contained the structural unit represented by General Formula (2) described above. The polymer 3 had a weight average molecular weight (Mw) of 65,000, a molecular weight distribution (Mw/Mn) of 1.81, and a glass transition temperature of 130° C.

A resin composition 5 (coating liquid) was prepared in the same manner as in Example 1, except that the polymer 3 was used in place of the polymer 1.

The resin composition 5 was applied onto a PET film in the same manner as in Example 1 to produce a laminate 6. At this time, the film thickness of the resin composition 5 measured immediately after coating on the PET film was 2 μm.

### Comparative Example 1

A photocurable material for optical nanoimprinting, PAK-01 (manufactured by Toyo Gosei Co., Ltd., not containing a fluorine-containing cyclic olefin polymer) was applied onto a PET film having a size of 10 cm×10 cm (LUMIRROR (registered trademark), manufactured by Toray Industries, Inc.) using a bar coater with a rod number 9 to form a liquid film having a uniform thickness. The film thickness of PAK-01 measured at this time was 9 μm.

Next, in a case where a hand roller was pressed and brought into close contact in order to cover with a Tohcello separator TMSPT18 (thickness: 50 μm, manufactured by Mitsui Chemicals Tohcello, Inc.) as a protective film, the applied PAK-01 leaked out from between the PET as the substrate and the protective film, and therefore a laminate could not be produced.

[Performance Evaluation]

Using the laminates 1 to 6 obtained in Examples 1 to 6, the above-mentioned [Procedure for producing concave-convex structure], [Evaluation of dimensional accuracy], and [Evaluation of dimensional accuracy of laminate with temporal changes] were carried out. The results are summarized in Table 1.

In Table 1, the numerical value of the dimensional accuracy with temporal changes was described by rounding off the second decimal place of the result obtained from the above-mentioned mathematical expression.

TABLE 1

| | | Example 1 | Example 2 | Example 3 | Example 4 |
|---|---|---|---|---|---|
| Laminate | | Laminate 1 | Laminate 2 | Laminate 3 | Laminate 4 |
| Base material layer | | PET | PET | Quartz | PET |
| Photocurable resin layer | | Resin composition 1 | Resin composition 2 | Resin composition 1 | Resin composition 3 |
| Fluorine-containing cyclic olefin | | Polymer 1 | Polymer 1 | Polymer 1 | Polymer 2 |
| polymer | | | | | |
| Photocurable compound | | Bis(3-ethyl-3- | Bis(3-ethyl-3 | Bis(3-ethyl-3 | Bis(3-ethyl-3 |
| (boiling point) | | oxetanylmethyl)ether/ | oxetanylmethyl)ether/ | oxetanylmethyl)ether/ | oxetanylmethyl)ether/ |
| | | 1,7-octadiene | 2-ethylhexylglycidyl | 1,7-octadiene | 1,7-octadiene |
| | | diepoxide | ether | diepoxide | diepoxide |
| | | 280° C./240° C. | 280° C./260° C. | 280° C./240° C. | 280° C./240° C. |
| Photocuring initiator | | CPI-210K | CPI-100P | CPI-210K | CPI-210K |
| Protective film layer | | Tohcello separator | Same as left | Same as left | Same as left |
| | | TMSPT18 | | | |
| Dimensions of | L1 | 250 | 251 | 250 | 252 |
| concave-convex | L2 | 250 | 249 | 250 | 248 |
| structure using | L3 | 500 | 500 | 500 | 499 |
| laminate having storage | | | | | |
| period of 1 hour (nm) | | | | | |
| Dimensional accuracy | L1ₑᵣ (1 day) | 1.0 | 1.0 | 1.0 | 1.0 |
| over time (1 day) of | L2ₑᵣ (1 day) | 1.0 | 1.0 | 1.0 | 1.0 |
| laminate | L3ₑᵣ (1 day) | 1.0 | 1.0 | 1.0 | 1.0 |
| Dimensional accuracy | L1ₑᵣ (7 days) | 1.0 | 1.0 | 1.0 | 1.0 |
| over time (7 days) of | L2ₑᵣ (7 days) | 1.0 | 1.0 | 1.0 | 1.0 |
| laminate | L3ₑᵣ (7 days) | 1.0 | 1.0 | 1.0 | 1.0 |

| | | | | |
|---|---|---|---|---|
| Long-term storage stability evaluation | ∘ | ∘ | ∘ | ∘ |

TABLE 2

| | | Example 5 | Example 6 | Comparative Example 1 |
|---|---|---|---|---|
| Laminate | | Laminate 5 | Laminate 6 | (It could not be produced |
| | | | | due to liquid dripping.) |
| Base material layer | | PET | PET | PET |
| Photocurable resin layer | | Resin composition 4 | Resin composition 5 | PAR-01 |
| Fluorine-containing cyclic olefin | | Polymer 1 | Polymer 3 | Not containing |
| polymer | | | | |
| Photocurable compound | | Methyl glycidyl ether | Bis(3-ethyl-3-oxetanylmethyl) | Acrylic monomer |
| (boiling point) | | 116° C. | ether/1,7-octadiene diepoxide | 92° C.-95° C. |
| | | | 280° C./240° C. | (Main material of mixture |
| | | | | of 3 types) |
| Photocuring initiator | | CPI-210K | CPI-210K | Not clear |
| Protective film layer | | Tohcello separator | Same as left | Same as left |
| | | TMSPT18 | | |
| Dimensions of | L1 | 251 | 250 | — |
| concave-convex | L2 | 249 | 250 | — |
| structure using | L3 | 500 | 500 | — |
| laminate having storage | | | | |
| period of 1 hour (nm) | | | | |
| Dimensional accuracy | L1ₑᵣ (1 day) | 0.8 | 1.0 | — |
| over time (1 day) of | L2ₑᵣ (1 day) | 1.2 | 1.0 | — |
| laminate | L3ₑᵣ (1 day) | 0.5 | 1.0 | — |
| Dimensional accuracy | L1ₑᵣ (7 days) | 0.7 | 1.0 | — |
| over time (7 days) of | L2ₑᵣ (7 days) | 1.3 | 1.0 | — |
| laminate | L3ₑᵣ (7 days) | 0.3 | 1.0 | — |

| | | | |
|---|---|---|---|
| Long-term storage stability evaluation | x | ∘ | — |

From Examples 1 to 6, it was shown that a concave-convex structure can be produced by preparing a laminate including a base material layer, a photocurable resin layer containing a fluorine-containing cyclic olefin polymer, a photocurable compound and a photocuring initiator, and a protective film layer in this order, peeling the protective film layer, pressing the mold, and irradiating light. In other words, it was shown that the concave-convex structure can be produced without applying a resin composition containing an organic solvent immediately before carrying out the imprinting, and the emission of an organic compound can be substantially eliminated in a case where the concave-convex structure is produced by the optical nanoimprint method.

In particular, looking at the values of L1, L2, and L3 in Examples 1 to 6, the dimensions of the mold are accurately reproduced with an accuracy of about ±1 to 2 nm. In other words, it can be seen that not only the concave-convex structure can be produced, but also a fine imprint pattern can be obtained with sufficient accuracy for practical use. (It is considered that the reason for this is that the mold releasability was good because the photocurable resin layer contained a fluorine-containing cyclic olefin polymer.)

In a case where Examples 1 to 6 were analyzed in more detail, from the evaluation results of the dimensional accuracy of the laminates of Examples 1 to 4 and 6 and Example 5 over time (1 day/7 days), it was found that, by using a compound having a relatively high boiling point as the photocurable compound, it is possible to obtain a concave-convex pattern having almost the same dimension as that of the concave-convex pattern obtained by using a laminate 1 hour after the production, even in a case where a laminate 1 day or 7 days after the production was used.

In other words, it was found that, by selecting a compound having a relatively high boiling point as the photocurable compound, it is possible to obtain a laminate that can be stably stored for a long period of time, and can accurately transfer a fine concave-convex pattern having a certain dimension even in a case where it is used after storage.

In all of Examples 1 to 6, the “peeling step” could be carried out without any particular problem. That is, at the time of the peeling step, the protective film layer could be peeled cleanly without any trouble such as a part of the photocurable resin layer peeling off from the base material layer.

In addition, it was confirmed that, in a case where the nanoimprint process was carried out several times using the concave-convex structure obtained in Examples 1 to 6 as a replica mold, a good concave-convex pattern could be produced, and there was sufficient shape retention (durability) as the replica mold.

Further, in Examples 1 to 6, a three-layered laminate could be produced without liquid dripping, whereas in Comparative Example 1, liquid dripping occurred and a three-layered laminate could not be produced satisfactorily. It is considered that this is partly because the photocurable resin layer was moderately rigid and contained a fluorine-containing cyclic olefin polymer, which made it possible to have an appropriate ‘hardness’ after application, and therefore unintended flow of the photocurable resin layer was suppressed.

[Additional Evaluation: Formation of Concave-Convex Structure on Quartz Substrate by Plasma Etching]

The surface of the quartz substrate obtained in Example 3 on which the photocured product was formed was plasma-etched under an oxygen atmosphere, and then the gas atmosphere was switched to tetrafluoromethane to plasma-etch the quartz surface. Thereafter, the plasma etching was carried out again under an oxygen atmosphere in order to remove the photocured product remaining on the quartz substrate.

As described above, the photocured product on the quartz substrate obtained in Example 3 was used as an etching mask to process a concave-convex shape on the quartz substrate surface.

The concave-convex shape on the quartz substrate surface had L1=250 nm, L2=250 nm, and L3=500 nm. That is, a shape substantially the same as the concave-convex shape of the photocured product could be formed on the quartz substrate surface. From this, it was confirmed that the photocurable resin layer in the laminate according to the present embodiment was also effective as an etching mask.

This application claims priority based on Japanese Patent Application No. 2018-006980 filed on Jan. 19, 2018, the disclosure of which is incorporated herein in its entirety.

1. A method for producing a concave-convex structure, the method comprising:
a preparation step of preparing a laminate including a base material layer, a photocurable resin layer containing a fluorine-containing cyclic olefin polymer (A), a photocurable compound (B) and a photocuring initiator (C), and a protective film layer in this order;
a peeling step of peeling the protective film layer of the laminate;
a pressing step of pressing a mold against the photocurable resin layer exposed in the peeling step; and
a light irradiation step of irradiating the photocurable resin layer with light,
wherein a concave-convex structure having an inverted concave-convex pattern of the mold is produced.

2. The method for producing a concave-convex structure according to claim 1,
wherein a mass ratio ((A)/(B)) of a content of the fluorine-containing cyclic olefin polymer (A) to a content of the photocurable compound (B) in the photocurable resin layer is equal to or more than 1/99 and equal to or less than 80/20.

3. The method for producing a concave-convex structure according to claim 1,
wherein the photocurable compound (B) contains a cationically polymerizable ring-opening polymerizable compound.

4. The method for producing a concave-convex structure according to claim 1,
wherein the photocurable compound (B) has a boiling point of equal to or higher than 150° C. and equal to or lower than 350° C. at 1 atm.

5. The method for producing a concave-convex structure according to claim 1,
wherein the fluorine-containing cyclic olefin polymer (A) includes a structural unit represented by General Formula (1). 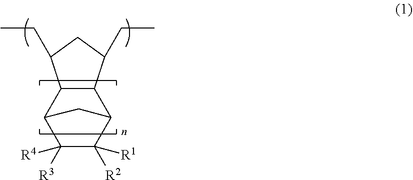
in General Formula (1),
at least one of R¹ to R⁴ is a fluorine-containing group selected from the group consisting of fluorine, a fluorine-containing alkyl group having 1 to 10 carbon atoms, a fluorine-containing alkoxy group having 1 to 10 carbon atoms, and a fluorine-containing alkoxyalkyl group having 2 to 10 carbon atoms,
in a case where R¹ to R⁴ are not a fluorine-containing group, R¹ to R⁴ are an organic group selected from the group consisting of hydrogen, an alkyl group having 1 to 10 carbon atoms, an alkoxy group having 1 to 10 carbon atoms, and an alkoxyalkyl group having 2 to 10 carbon atoms, and
R¹ to R⁴ may be the same as or different from each other, and R¹ to R⁴ may be bonded to each other to form a ring structure, and n represents an integer of 0 to 2.

6. The method for producing a concave-convex structure according to claim 1,
wherein the base material layer is formed of a resin film.

7. A laminate to be used in a method for producing a concave-convex structure having an inverted concave-convex pattern of a mold, the laminate comprising:
a base material layer;
a photocurable resin layer containing a fluorine-containing cyclic olefin polymer (A), a photocurable compound (B) and a photocuring initiator (C); and
a protective film layer in this order.

8. The laminate according to claim 7,
wherein a mass ratio ((A)/(B)) of a content of the fluorine-containing cyclic olefin polymer (A) to a content of the photocurable compound (B) in the photocurable resin layer is equal to or more than 1/99 and equal to or less than 80/20.

9. The laminate according to claim 7,
wherein the photocurable compound (B) contains a cationically polymerizable ring-opening polymerizable compound.

10. The laminate according to claim 7,
wherein the photocurable compound (B) has a boiling point of equal to or higher than 150° C. and equal to or lower than 350° C. at 1 atm.

11. The laminate according to claim 7,
wherein the fluorine-containing cyclic olefin polymer (A) includes a structural unit represented by General Formula (1). 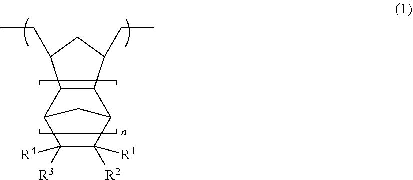
in General Formula (1),
at least one of R¹ to R⁴ is a fluorine-containing group selected from the group consisting of fluorine, a fluorine-containing alkyl group having 1 to 10 carbon atoms, a fluorine-containing alkoxy group having 1 to 10 carbon atoms, and a fluorine-containing alkoxyalkyl group having 2 to 10 carbon atoms,
in a case where R¹ to R⁴ are not a fluorine-containing group, R¹ to R⁴ are an organic group selected from the group consisting of hydrogen, an alkyl group having 1 to 10 carbon atoms, an alkoxy group having 1 to 10 carbon atoms, and an alkoxyalkyl group having 2 to 10 carbon atoms, and
R¹ to R⁴ may be the same as or different from each other, and R¹ to R⁴ may be bonded to each other to form a ring structure, and
n represents an integer of 0 to 2.

12. The laminate according to claim 7,
wherein the base material layer is formed of a resin film.

13. A method for producing the laminate according to claim 7, the method comprising:
a step of forming a photocurable resin layer containing a fluorine-containing cyclic olefin polymer (A), a photocurable compound (B) and a photocuring initiator (C) on a surface of a base material layer; and
a step of forming a protective film layer on the surface of the photocurable resin layer.
